(19) United States
(12) Patent Application Publication
(10) Pub. No.: US 2007/0087579 A1
(43) Pub. Date: Apr. 19, 2007

(54) Semiconductor device manufacturing method

(75) Inventors: Kanako Kitayama, Toyama (JP); Sadayoshi Horii, Toyama (JP)

Correspondence Address: OLIFF & BERRIDGE, PLC, P.O. BOX 19928, ALEXANDRIA, VA, 22320, US

(73) Assignee: Hitachi Kokusai Electric Inc., Tokyo (JP)

(21) Appl. No.: 10/574,893

(22) PCT Filed: Mar. 8, 2005
(86) PCT No.: PCT/JP05/03983

§ 371 Date: Aug. 9, 2006

(30) Foreign Application Priority Data
Mar. 31, 2004 (JP) 2004-106161

(51) Int. Cl. H01L 21/31; H01L 21/469

(52) U.S. Cl. 438/778; 438/780; 438/794

(57) ABSTRACT

A semiconductor device manufacturing method by which a process chamber can be self-cleaned, while keeping a temperature in the process chamber low or a semiconductor device manufacturing method by which a high-k film adhering in the process chamber can be effectively removed. The method is provided with a pre-coat process, a film forming process and a cleaning process. Activated F* or Cl* by remote plasma passes through a high-k film (31), reacts to a pre-coat film (30) composed of SiO2 or Si. Since the pre-coat film (30) peels in pieces, the high-k film over the pre-coat film can be removed together.

### TECHNICAL FIELD

The present invention relates to a method of manufacturing a semiconductor device.

### BACKGROUND ART

In a manufacture of the semiconductor device, there is a cleaning process of removing a film having adhered to a processing chamber inside. It is publicly known that, in this cleaning process, a self-cleaning is performed by using a gas reacting with the adhered film, thereby reducing a downtime of an apparatus and improving an availability factor. Further, there are also known a method in which, after the cleaning, an SiO₂ film and an SiF₄ film are pre-coated and thereafter the SiO₂ film and the SiF₄ film are formed (refer to Patent Document 1, column of “Prior Art”), and a method in which, after the cleaning, a CF film and an a-C film are pre-coated and thereafter the CF film is formed (refer to the Patent Document 1, column of “Mode for Carrying Out the Invention”).

Patent Document 1: JP-A-10-144667

### DISCLOSURE OF THE INVENTION

### Problems that the Invention is to Solve

However, in the prior arts, there is not established a method of self-cleaning a High-k film. Here, the High-k film means a high permittivity insulating film, and it is one which has a permittivity higher than SiO₂ and whose permittivity is about 10-100, and there are included HfO₂, ZrO₂, La₂O₃, Pr₂O₃, Al₂O₃, and the like.

As a cleaning method in a case where the High-k film has adhered to the processing chamber inside, there is considered a method in which a ClF₃ gas is introduced into the processing chamber to thereby be reacted with the High-k film, thereby performing an etching by a thermal decomposition. For example, a reaction formula in a case where the High-k film is HfO₂ is as follows.
HfO₂+4Cl*→HfCl₄↑+O₂

Here, the * denotes the fact that it is an active species having been activated by a plasma.

However, in the method like this, the etching cannot be performed unless there are obtained high temperatures of about 400° C.-500° C., and actually the cleaning has been difficult because a material (e.g., Al) constituting the processing chamber inside is impaired, or this is molten.

A 1st object of the present invention exists in providing a method of manufacturing a semiconductor device, in which the self-cleaning can be performed while suppressing the temperature of the processing chamber inside to a low temperature.

A 2nd object of the present invention exists in providing a method of manufacturing a semiconductor device, in which the High-k film having adhered to the processing chamber inside can be effectively removed.

### MEANS FOR SOLVING THE PROBLEMS

In order to solve the above problems, a 1st characteristic of the present invention exists in a method of manufacturing a semiconductor device, comprising the steps of: pre-coating a pre-coating film, which differs from a film to be formed to a substrate, to a processing chamber inside, forming the film to the substrate in the processing chamber after the pre-coating, and cleaning the processing chamber inside by supplying a reactant into the processing chamber after forming the film, wherein, in the cleaning step, a film adhered to the processing chamber inside is removed together with the pre-coating film by reacting the reactant with the pre-coating film without substantially reacting with the film adhered to the processing chamber inside in the film forming step.

Desirably, in the film formation step, a High-k film is formed. Further, desirably, the High-k film is a film containing Hf. Further, desirably, the film containing Hf is an HfO₂ film or an Hf silicate film. Further, desirably, the pre-coating film is a film containing Si. Further, desirably, the film containing Si is a film of at least one kind selected from a group consisting of SiO₂, Si or SiC. Further, desirably, the reactant used in the cleaning step contains F or Cl. Further, desirably, the reactant used in the cleaning step is an active species obtained by activating a gas containing F or Cl by a plasma, or an active species obtained by activating a mixed gas of a gas containing F or Cl and Ar by a plasma. Further, desirably, the reactant used in the cleaning step is F or Cl, which has been activated. Further, desirably, in the cleaning step, a cleaning temperature is made a temperature within a range not lower than 100° C. and not higher than 400° C. Further, desirably, in the processing chamber inside, an Al-made member exists. Further, desirably, the processing chamber is a cold wall type.

A 2nd characteristic of the present invention exists in a method of manufacturing a semiconductor device, comprising the steps of: pre-coating a pre-coating film, which differs from the film to be formed to a substrate, to a processing chamber inside, forming the film to the substrate in the processing chamber after the pre-coating, and cleaning the processing chamber-inside by supplying a reactant into the processing chamber after forming the film, wherein, in the cleaning step, a film adhered to the processing chamber inside is removed together with the pre-coating film by making such that an etching rate of the pre-coating film becomes higher than an etching rate of the film adhered to the processing chamber inside in the film forming step.

Desirably, the etching rate of the pre-coating film is several times or more of the etching rate of the film adhered to the processing chamber inside in the film forming step.

A 3rd characteristic of the present invention exists in a method of manufacturing a semiconductor device, comprising the steps of: pre-coating a pre-coating film, which consists of a material other than a High-k film, to a substrate processing chamber inside, forming the High-k film to a substrate in the processing chamber after the pre-coating, and cleaning the processing chamber inside by supplying a reactant into the processing chamber after forming the film, wherein, in the cleaning step, the High-k film adhered to the processing chamber inside is removed together with the pre-coating film by making a cleaning temperature into a temperature of such a degree that the reactant reacts with the pre-coating film without reacting with the High-k film adhered to the processing chamber inside.

A 4th characteristic of the present invention exists in a method of manufacturing a semiconductor device, comprising the steps of: pre-coating a pre-coating film, which consists of a material other than a High-k film, to a substrate processing chamber inside, forming the High-k film to a substrate in the processing chamber after the pre-coating, and cleaning the processing chamber inside by supplying a reactant into the processing chamber after forming the film, wherein, in the cleaning step, a cleaning temperature is made a temperature within a range not lower than 100° C. and not higher than 400° C.

More desirably, the cleaning temperature is made a range not lower than 100° C. and not higher than 200° C.

### BRIEF DESCRIPTION OF THE DRAWINGS

FIG. 1 is a sectional view showing an apparatus for processing a substrate, which has been used in a first implementation mode according to the present invention.

FIG. 2 is a flowchart showing processes of manufacturing a semiconductor device in the first implementation mode according to the present invention.

FIG. 3 shows the apparatus for processing the substrate, which has been used in the first implementation mode of the present invention, wherein (a) is a sectional view showing a state of a processing chamber after a pre-coating, and (b) a sectional view showing a state of the processing chamber after a High-k film formation.

FIG. 4 is a sectional view showing an influence of a remote plasma on an interface in the first implementation mode according to the present invention.

FIG. 5 is a schematic diagram showing an apparatus for processing a substrate, which has been used in a second implementation mode according to the present invention.

FIG. 6 is a sequence diagram showing, in the second implementation mode according to the present invention, processes of an MOCVD film formation and a reforming.

FIG. 7 is a schematic diagram showing an apparatus for processing a substrate, which has been used in a third implementation mode according to the present invention.

FIG. 8 is a sequence diagram showing, in the third implementation mode according to the present invention, processes of the MOCVD film formation and the reforming.

### BEST MODE FOR CARRYING OUT THE INVENTION

Next, implementation modes of the present invention are explained on the basis of the drawings.

First Implementation Mode:

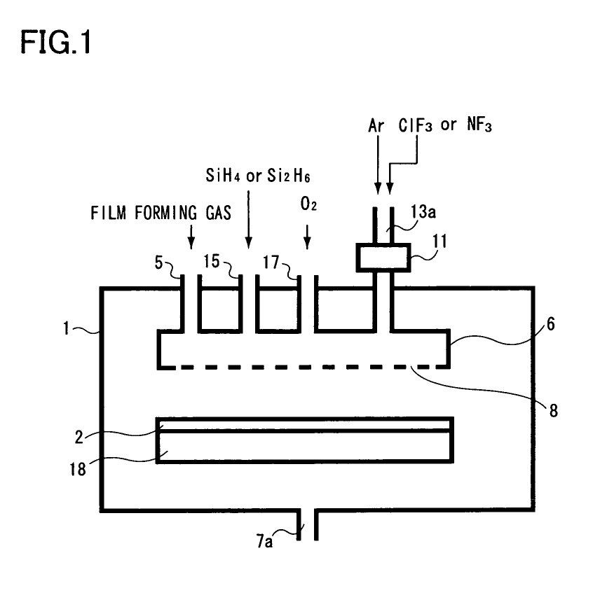

FIG. 1 is a schematic view showing one example of a leaf system CVD apparatus that is an apparatus for processing a substrate, which has been used in the first implementation mode.

A processing chamber 1 is cold wall type one having in its inside a heater unit 18, and a susceptor 2 is provided in an upper part of the heater unit 18. The substrate that is a processing object is mounted on the susceptor 2. Above this susceptor 2 there is provided a shower head 6 having many holes 8. To this shower head 6, there are connected a raw material supply pipe 5 for supplying a film forming gas, a cleaning gas supply pipe 13a for supplying a cleaning gas, a pre-coating gas supply pipe 15 for supplying a pre-coating gas, and an oxygen gas supply pipe 17 for supplying an oxygen gas, and thereby there is adapted such that the film forming gas, the cleaning gas, the pre-coating gas or the oxygen gas can be jetted like a shower into the processing chamber 1 from the shower head 6. To the cleaning gas supply pipe 13a there is connected a remote plasma unit 11, and Ar and F or Ar and Cl, which have been activated by this remote plasma unit 11, are supplied to the processing chamber 1. Further, to a lower part center of the processing chamber 1 there is connected an exhaust port 7a.

Incidentally, an inner wall of the processing chamber 1 is constituted by Al, the susceptor 2 by SiC, Al₂O₃ or AlN, the shower head 6 by Al, and the heater unit 18 by SUS (stainless steel) or AlN.

Next, while referring to FIG. 1 to FIG. 4, there is explained about a method of manufacturing a semiconductor device by using the above apparatus for processing the substrate.

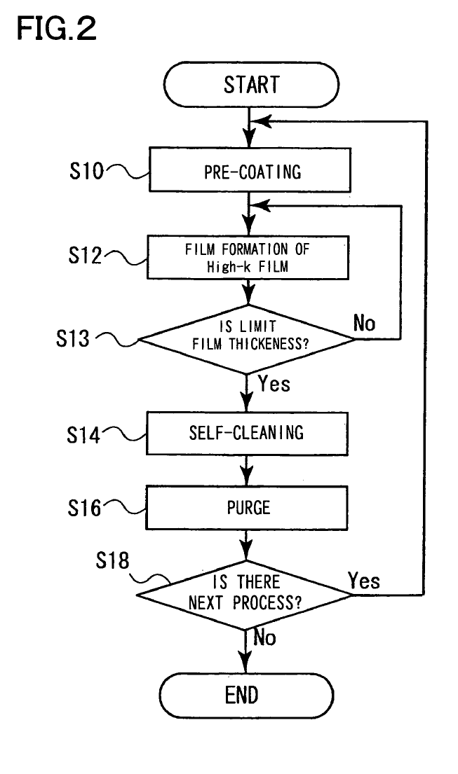

FIG. 2 is a flowchart for manufacturing the semiconductor device. First, in a step S10, by introducing SiH₄ or Si₂H₆ from the pre-coating gas supply pipe 15 and an O₂ gas from the oxygen supply pipe 17 to an inside, of the processing chamber 1 shown in FIG. 1, to which the film formation is not performed yet, an SiO₂ or Si film is previously thinly pre-coated to the inside of the processing chamber 1 by a CVD method.

As pre-coating conditions, it is desirable that a temperature is made 500-600° C., a pressure 100-10000 Pa, a gas flow rate of SiH₄ or Si₂H₆ 0.1-10 SLM and a gas flow rate of O₂ 0.1-10 SLM, and a film thickness of the SiO₂ or Si film is made 500-1000 Å.

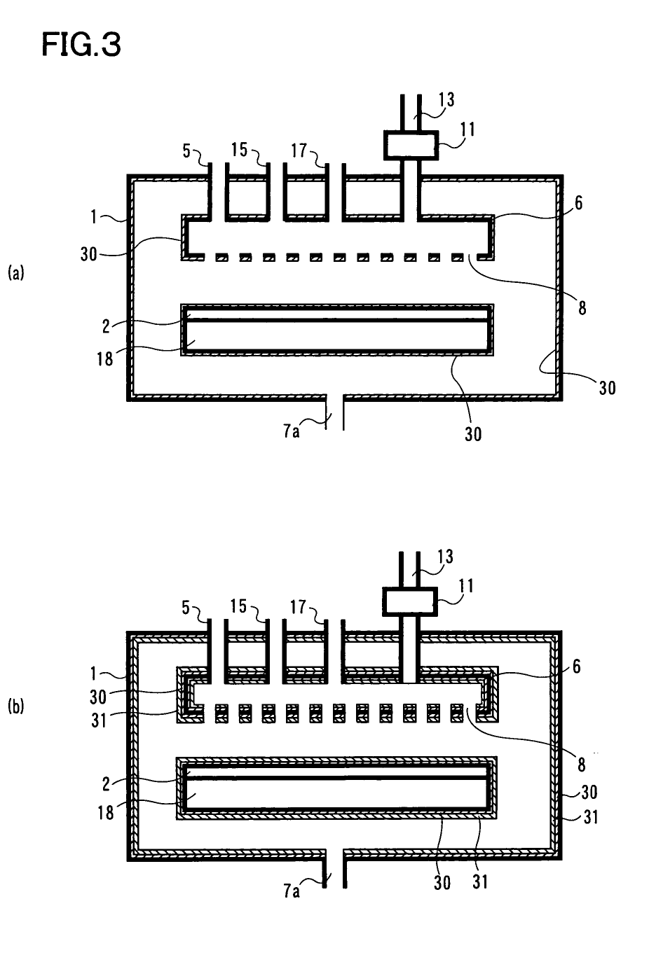

FIG. 3(a) shows a state of the processing chamber 1 inside after the pre-coating. A pre-coating film 30 is uniformly formed on an inner wall of the processing chamber 1, the susceptor 2, the shower head 6, the heater unit 18, and the like.

In a next step S12, the substrate is transported into the processing chamber 1 to thereby mount the substrate on the susceptor 2, a raw material gas is introduced from the raw material gas supply pipe 5, and the film formation of the High-k film is performed onto the substrate by the CVD method or an ALD method. As the raw material gas, there is used, for example, a gas obtained by vaporizing Hf[OC(CH₃)₂CH₂OCH₃]₄ (hereafter, abbreviated as Hf-(MMP)₄, where MMP:1 methoxy-2-methyl-2-propoxy)(organometallic raw material containing hafnium) that is an organic liquid raw material, thereby forming, e.g., an HfO₂ film or an HF silicate film.

As film formation conditions of the High-k film, it is desirable that the temperature is made 300-500° C., the pressure 50-200 Pa, a gas flow rate of the Hf-(MMP)₄ 0.01-0.5 sccm, and the HfO₂ film or the HF silicate film 2-5 nm. After forming the High-k film on the substrate, the substrate is transported out of the processing chamber 1.

FIG. 3(b) shows a state of the processing chamber 1 inside after the High-k film has been formed and the substrate has been transported out. A High-k film 31 is uniformly formed on the pre-coating film 30 having been formed on the inner wall of the processing chamber 1, the susceptor 2, the shower head 6, the heater unit 18, and the like.

Incidentally, the High-k film means the high permittivity insulating film, and is one which has the permittivity higher than SiO₂ and whose permittivity is about 10-100, and there are included HfO₂, ZrO₂, La₂O₃, Pr₂O₃, Al₂O₃, and the like, and it can be formed by using, for the raw material, the organometallic raw material containing each of the metal elements.

In a next step S13, it is judged whether or not a film thickness having deposited to the processing chamber 1 inside has reached to a limit film thickness (about 50-1000 nm), i.e., a film thickness of such a degree as generating particles. In this step S13, in a case where it has been judged that the film thickness having deposited to the processing chamber 1 inside has reached to the limit film thickness, it shifts to a next self-cleaning step S14. In a case where it has been judged that the film thickness having deposited to the processing chamber 1 inside does not reach to the limit film thickness, it returns to the step S12 to thereby perform the film formation of the High-k film to a new substrate, and the film formation of the High-k film to the substrate is repeated till the film thickness having deposited to the processing chamber 1 inside reaches to the limit film thickness.

In the next step S14, the self-cleaning of the processing chamber 1 inside is performed. When performing the self-cleaning, as the cleaning gas, a ClF₃ or NF₃ gas as a gas containing F or Cl is introduced, together with an Ar gas (gas for igniting a plasma), from the cleaning gas supply pipe 13a and, by activating it by the plasma in the remote plasma unit 11, F* or Cl* (the * denotes one of an excitation state) as a reactant is generated and it is introduced to the inside of the processing chamber 1.

As cleaning conditions, it is desirable that the temperature is made 100-400° C., desirably 100-200° C., the pressure 50-200 Pa, a gas flow rate of the ClF₃ or the NF₃ 0.5-2 SLM and a flow rate of the Ar 0.5-2 SLM, and it is performed with an output (electric power) during a remote plasma generation being made 5 kW.

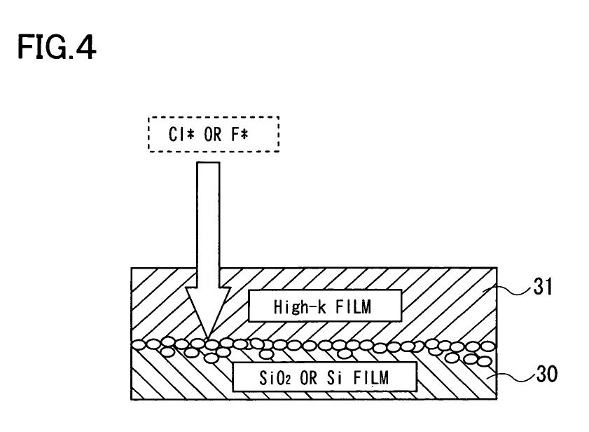

As shown in FIG. 4, since the F* or the Cl*, which has been activated by the remote plasma unit 11, passes through the High-k film 31, reacts with the pre-coating film 30 consisting of SiO₂ or Si and thus the pre-coating film 30 exfoliates into pieces, it is possible to remove together also the High-k film existing thereon.

That is, the SiO₂ or Si film disintegrates by the fact that the F* or the Cl*, which has been generated by the remote plasma, passes through the High-k film without substantially reacting with the High-k film and reacts with the pre-coating film in an interface with the pre-coating film 30, i.e., by a reaction of
SiO₂+4F*→O₂+SiF₄↑
or
SiO₂+4Cl*→O₂+SiCl₄↑.

Here, an etching rate of the SiO₂ or Si film by the F* or the Cl* is 1-10 nm/minute, whereas an etching rate of the High-k film by the F* or the Cl* is 0.5 nm/minute or less and, depending on the cleaning conditions, there is also that fact that the High-k film is etched very slightly. However, even in that case, the etching rate of the High-k film is 1/20-½ or less of the etching rate of the SiO₂ film or the Si film, so that it follows that the SiO₂ or Si film is intensively etched.

In the case where the remote plasma is used, since high temperatures are unnecessary and, if the temperature is not lower than 100° C. and not higher than 400° C., it is possible to react the F* or the Cl* with the pre-coating film without substantially reacting with the High-k film, an influence on the inside of the processing chamber 1 is a little as well.

In a next step S16, there is performed a purge of the processing chamber 1 inside by an N₂ gas that is an inert gas having been introduced from the gas supply pipe 15 or 17, thereby discharging the cleaning gas having remained in the processing chamber 1 inside, a substance having been formed at a cleaning time, and pre-coating film particles and High-k film particles, which have exfoliated by the cleaning.

And, in a next step S18, it is judged whether or not there is a next process, in a case where there is the next process it returns to the step S10, and in a case where there is not the next process the processing ends.

Second Implementation Mode:

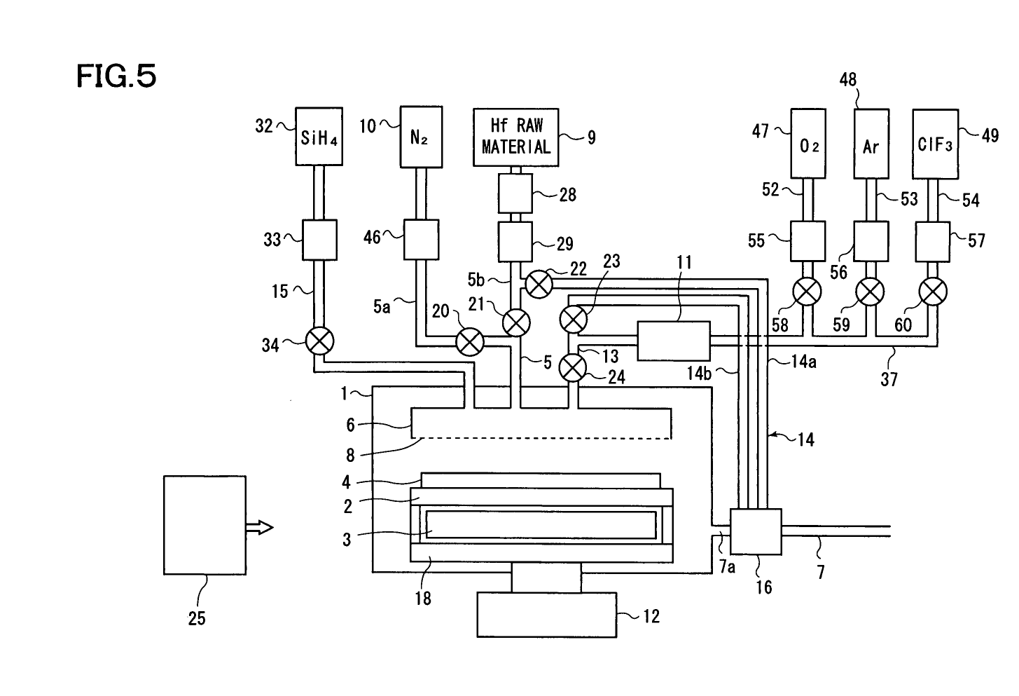

FIG. 5 is a schematic view showing one example of a leaf system CVD apparatus that is an apparatus for processing a substrate, which has been used in the second implementation mode.

This second implementation mode is one in which the present invention has been applied to a case where the HfO₂ film of an amorphous state is formed by a film forming method repeating the film formation by an MOCVD method and a reforming processing of the film.

As shown in FIG. 5, in the processing chamber 1, there is provided a hollow heater unit 18 whose upper part opening has been covered by the susceptor 2. There is adapted such that a heater 3 is provided inside the heater unit 18, and a substrate 4 mounted on the susceptor 2 is heated by the heater 3. The substrate 4 mounted on the susceptor 2 is, e.g., a semiconductor silicon wafer, a glass substrate, and the like.

There is adapted such that a substrate rotation unit 12 is provided outside the processing chamber 1, and it is possible to rotate the substrate 4 on the susceptor 2 by rotating the heater unit 18 in the processing chamber 1 by the substrate rotation unit 12. The substrate 4 is rotated in order to rapidly, uniformly perform a processing to the substrate in a film formation process and a reforming process, which are mentioned later, in a substrate face.

Further, above the susceptor 2 in the processing chamber 1 there is provided the shower head 6 having the many holes 8. To this shower head 6, there are connected in common the pre-coating gas supply pipe 15 for supplying the pre-coating gas, the raw material supply pipe 5 for supplying the film forming gas, and a radical supply pipe 13 for supplying a radical capable of activating a reforming gas and a radical capable of activating the cleaning gas, and thereby there is adapted such that the pre-coating gas, the film forming gas or the radicals can be jetted like the shower into the processing chamber 1 from the shower head 6. Here, the shower head 6 constitutes the same supply port for supplying respectively the pre-coating gas to be supplied into the processing chamber 1 in a pre-coating process, the film forming gas to be supplied to the substrate 4 in the film formation process, and the radical capable of activating the reforming gas to be supplied to the substrate 4 in a reforming process and the radical capable of activating the cleaning gas to be supplied into the processing chamber 1 in a cleaning process.

Outside the processing chamber 1, there are provided a pre-coating gas supply unit 32 that is a supply source of the pre-coating gas, a mass flow controller 33 as a flow rate control means for controlling a supply quantity of the pre-coating gas, and a valve 34. To the pre-coating gas supply pipe 15, there are connected the pre-coating gas supply unit 32, the mass flow controller 33 and the valve 34, and thereby there is adapted such that the pre-coating gas is supplied to the processing chamber 1 inside by opening the valve 34 in a process of pre-coating the processing chamber 1 inside. The pre-coating gas is the SiH₄ or the Si₂H₆ similarly to the first implementation mode which has been mentioned before.

Further, outside the processing chamber 1, there are provided a film forming raw material supply unit 9 for supplying an organic liquid raw material as a film forming raw material, a liquid flow rate control device 28 as a flow rate control means for controlling a liquid supply flow rate of the film forming raw material, and a vaporizer 29 for vaporizing the film forming raw material. Further, there are provided an inert gas supply unit 10 for supplying an inert gas as a non-reactive gas, and a mass flow controller 46 as a flow rate control means for controlling a supply flow rate of the inert gas. As the film forming raw material there is used an organic material such as Hf-(MMP)₄. Further, as the inert gas there is used Ar, He, N₂ or the like. By making a raw material gas supply pipe 5b having been provided in the film forming raw material unit 9 and an inert gas supply pipe 5a having been provided in the inert gas supply unit 10 into one piece, there is provided the raw material supply pipe 5 connected to the shower head 6. There is adapted such that, in the film formation process of forming the HfO₂ film onto the substrate 4, the raw material supply pipe 5 supplies a mixed gas of the film forming gas and the inert gas to the shower head 6. In the raw material gas supply pipe 5b and the inert gas supply pipe 5a there are provided respectively valves 21, 20, and it becomes possible to control the supply of the mixed gas of the film forming gas and the inert gas by opening/closing these valves 21, 20.

Further, outside the processing chamber 1, there is provided the reactant activation unit (remote plasma unit) 11 becoming a plasma source for forming the radical as the reactant by activating the gas by the plasma. It is preferable that, in a case where an organic material is used as the raw material, the radical as a secondary raw material used in the reforming process which reforms the HfO₂ film having been formed in the film formation process is an oxygen radical (O*) obtained by activating, e.g., an oxygen containing gas (O₂, N₂O, NO, or the like). This is because, by the oxygen radical, it is possible to efficiently implement a processing of removing impurities such as C and H just after the HfO₂ film formation. Further, it is preferable that the radical used in the cleaning process of removing the HfO₂ film having adhered to the processing chamber 1 inside in the film formation process is a radical (Cl*, F*, or the like) obtained by activating ClF₃ or NF₃. A processing in which, in the reforming process, the film is oxidized in an oxygen radical atmosphere having been formed by activating the oxygen containing gas (O₂, N₂O, NO, or the like) by the plasma is called a remote plasma oxidation processing (RPO [remote plasma oxidation] processing).

In an upstream side of the reactant activation unit 11, there is provided a gas supply pipe 37. There is adapted such that to this gas supply pipe 37 there are connected, through supply pipes 52, 53 and 54, an oxygen supply unit 47 for supplying the oxygen containing gas, e.g., oxygen (O₂), an Ar supply unit 48 for supplying argon (Ar) that is a gas generating the plasma, and a ClF₃ supply unit 49 for supplying chlorine fluoride (ClF₃) or nitrogen fluoride (NF₃), thereby supplying the O₂ and the Ar which are used in the reforming process and the ClF₃ or the NF₃, which is used in the cleaning process. In the oxygen supply unit 47, the Ar supply unit 48 and the ClF₃ supply unit 49, there are provided respectively mass flow controllers 55, 56, 57 as flow rate control means, each of which controls a supply flow rate of the gas. In the supply pipes 52, 53 and 54, there are provided respectively valves 58, 59 and 60 and, by opening/closing these valves 58, 59 and 60, it becomes possible to control supplies of the O₂ gas, the Ar gas and the ClF₃ (or NF₃).

There is adapted such that, in a downstream side of the reactant activation unit 11, there is provided the radical supply pipe 13 connected to the shower head 6 and, in the reforming process or the cleaning process, the oxygen radical (O*) or the chlorine radical (Cl*) (or the fluorine radical (F*)) is supplied to the shower head 6. Further, a valve 24 is provided in the radical supply pipe 13 and, by opening/closing the valve 24, it becomes possible to control the supply of the radical.

An exhaust port 7a is provided in the processing chamber 1, and the exhaust port 7a is connected to an exhaust pipe 7 communicating with a harm removal device (not shown in the drawing). In the exhaust pipe 7, there is installed a raw material recovery trap 16 for recovering the film forming raw material. This raw material recovery trap 16 is used in common for the film formation process and the reforming process. An exhaust line is constituted by the exhaust port 7a and the exhaust pipe 7.

Further, in the raw material supply pipe 5b and the radical supply pipe 13, there are provided respectively a raw material gas bypass pipe 14a connected to the raw material recovery trap 16 having been provided in the exhaust pipe 7, and a radical bypass pipe 14b (there is also a case where these are mentioned merely as a bypass pipe 14). In the raw material gas bypass pipe 14a and the radical bypass pipe 14b, there are provides respectively valves 22, 23. When supplying the film forming gas to the substrate 4 in the processing chamber 1 in the film formation process by opening/closing these valves, the processing chamber 1 is previously exhausted so as to bypass it through the radical bypass pipe 14b and the raw material recovery trap 16 without stopping the supply, from the remote plasma unit 11, of the radical used in the reforming process. Further, when supplying the radical to the substrate 4 in the reforming process, the processing chamber 1 is previously exhausted so as to bypass it through the raw material gas bypass pipe 14a and the raw material recovery trap 16 without stopping the supply, from the vaporizer 29, of the film forming gas used in the film formation process.

And, there is provided a control device 25 which, by controlling an open/close or the like of the above valves 20-24, controls so as to continuously repeat, by plural times, the film formation process of forming the HfO₂ film on the substrate 4 in the processing chamber 1, and the reforming process of removing the impurities, such as C and H, that are specified elements in the HfO₂ film having been formed in the film formation process by a plasma processing having used the reactant activation unit 11.

Next, there is explained about procedures of manufacturing the semiconductor device by using the apparatus for processing the substrate of the above-mentioned constitution. In these procedures, there are included a pre-coating process, a process of depositing a high quality HfO₂ film to the substrate, and the cleaning process. Further, in the process of depositing the high quality HfO₂ film to the substrate, there are included a temperature raising process, the film formation process, a purge process, and the reforming process.

First, the SiO₂ or Si film is thinly pre-coated previously to the inside of the processing chamber 1 by the CVD method by opening the valve 34 having been provided in the supply pipe 15, flow-rate-controlling the SiH₄ or Si₂H₆ gas which has been supplied from the pre-coating gas supply unit 32, and introducing it to the processing chamber 1 in which the film formation processing is not performed yet (pre-coating process). Incidentally, in a case where the SiO₂ film is used as the pre-coating film, the O₂ gas having been supplied from the oxygen supply unit 47 by simultaneously opening the valve 58 having been provided in the supply pipe 52 and the valve 24 having been provided in the radical supply pipe 13 is introduced into the processing chamber 1 while being flow-rate-controlled by the mass flow controller 55. At this time, the reactant activation unit 11 does not operate, and the O₂ gas is supplied without being activated.

Next, the substrate 4 is transported into the processing chamber 1, the substrate 4 is mounted on the susceptor 2 in the processing chamber 1, and the substrate 4 is uniformly heated to temperatures of 300-500° C. by supplying the electric power to the heater 3 while rotating the substrate 4 by the substrate rotation unit 12. At a transportation time of the substrate 4 and at a substrate heating time, if the inert gas such as Ar, He and N₂ is always flowed by opening the valve 20 having been provided in the inert gas supply pipe 5a, it is possible to prevent adhesions of particles and metallic contaminants to the substrate 4.

After ending the temperature raising process, it enters into the film formation process. In the film formation process, the Hf-(MMP)₄ having been supplied from the film forming raw material supply unit 9 is flow-rate-controlled by the liquid flow rate control device 28, and vaporized by being supplied to the vaporizer 29. By opening the valve 21 having been provided in the raw material gas supply pipe 5b, the vaporized raw material gas is supplied onto the substrate 4 through the shower head 6. Also at this time, there is made so as to agitate the film forming gas by always flowing the inert gas (N₂ or the like) from the inert gas supply unit 10 with the valve 20 being opened intact. If the film forming gas is diluted by the inert gas, it becomes easy to be agitated. The film forming gas supplied from the raw material gas supply pipe 5b and the inert gas supplied from the inert gas supply pipe 5a are mixed in the raw material supply pipe 5 and guided to the shower head 6 as the mixed gas, and supplied like the shower onto the substrate 4 on the susceptor 2 while passing through the many holes 8.

By implementing the supply of this mixed gas for a predetermined time, on the substrate 4 there is formed the HfO₂ film as an interface layer (1st insulating layer) with the substrate. During this time, since the substrate 4 is kept at a predetermined-temperature (film-forming temperature) by the heater 3 while being rotated, a uniform film can be formed over a substrate face. Next, by closing the valve 21 having been provided in the raw material gas supply pipe 5b, the supply of the raw material gas to the substrate 4 is stopped. Incidentally, on this occasion, there is made so as not to stop the supply of the film forming gas from the vaporizer 29 by opening the valve 22 having been provided in the raw material gas bypass pipe 14a and exhausting the film forming gas by bypassing the processing chamber 1 by the raw material gas bypass pipe 14a. Since it takes a time till the liquid raw material is vaporized and the raw material gas having been vaporized is stably supplied, if it is previously flowed so as to bypass the processing chamber 1 without stopping the supply of the film forming gas from the vaporizer 29, in a next film formation process it is possible to immediately supply the film forming gas to the substrate 4 only by switching the flow by the valve.

After ending the film formation process, it enters into a purge process. In the purge process, a residual gas is removed by purging the processing chamber 1 inside by the inert gas. Incidentally, in the film formation process, since the valve 20 is opened intact and the inert gas (N₂ or the like) is always flowing from the inert gas supply unit 10 to the processing chamber 1 inside, it follows that the purge is performed at the same time as the valve 21 is closed and the supply of the raw material gas to the substrate 4 is stopped.

After ending the purge process, it enters into the reforming process. The reforming process is performed by the RPO (remote plasma oxidation) processing. In the reforming process, the valve 59 having been provided in the supply pipe 53 is opened, and the Ar having been supplied from the Ar supply unit 48 is supplied to the reactant activation unit 11 while being flow-rate-controlled by the mass flow controller 56, thereby generating an Ar plasma. After the Ar plasma has been generated, the valve 58 having been provided in the supply pipe 52 is opened, and the O₂ having been supplied from the oxygen supply unit 47 is supplied to the reactant activation unit 11, which is generating the Ar plasma, while being flow-rate-controlled by the mass flow controller 55, thereby activating the O₂. By this, the oxygen radical is generated. By opening the valve 24 having been provided in the radical supply pipe 13, a gas containing the oxygen radical, as a secondary raw material, is supplied from the reactant activation unit 11 onto the substrate 4 through the shower head 6. During this time, since the substrate 4 is kept at a predetermined temperature (the same temperature as a film forming temperature) by the heater 3 while being rotated, it is possible to rapidly, uniformly remove the impurities such as C and H from the HfO₂ film having been formed on the substrate 4 in the film formation process.

Thereafter, the valve 24 having been provided in the radical supply pipe 13 is closed, thereby stopping the supply of the oxygen radical to the substrate 4. Incidentally, on this occasion, by opening the valve 23 having been provided in the radical bypass pipe 14b, the gas containing the oxygen radical (O*) is exhausted while bypassing the processing chamber 1 by the radical bypass pipe 14b, thereby making such that the supply of the gas containing the oxygen radical (O*) from the reactant activation unit 11 is not stopped. Since the oxygen radical (O*) takes a time from its generation till it is stably supplied, if it is previously flowed so as to bypass the processing chamber 1 without stopping the supply of the gas containing the oxygen radical (O*) from the reactant activation unit 11, it is possible to immediately supply the gas containing the oxygen radical (O*) to the substrate 4 only by switching the flow by the valve.

After ending the reforming process, it enters into the purge process again. In the purge process, the residual gas is removed by purging the processing chamber 1 inside by the inert gas. Incidentally, also in the reforming process, since the valve 20 is opened intact and the inert gas (N₂ or the like) is always flowing from the inert gas supply unit 10 to the processing chamber 1 inside, the purge is performed at the same time as the supply of the oxygen radical to the substrate 4 is stopped.

After ending the purge process, it enters into the film formation process again and, by closing the valve 22 having been provided in the raw material gas bypass pipe 14a and opening the valve 21 having been provided in the raw material gas supply pipe 5b, the film forming gas is supplied onto the substrate 4 through the shower head 6, thereby depositing the HfO₂ film again onto the thin film having been formed in the film formation process in the previous time.

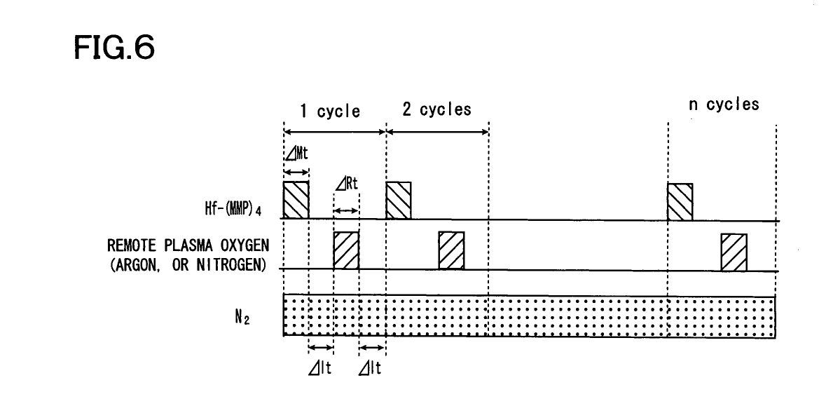

A cycle processing in which the film formation process→the purge process→the reforming process→the purge process like the above is repeated by plural times is intelligibly explained by using a film formation sequence diagram shown in FIG. 6.

That is, if the substrate 4 is mounted on the susceptor 2 in the processing chamber 1 and the temperature of the substrate 4 has stabilized,

(1) The Hf-(MMP)₄ is introduced, together with a diluted N₂, into the processing chamber 1 for ΔMt seconds.

(2) Thereafter, if the introduction of the Hf-(MMP)₄ is stopped, the processing chamber 1 inside is purged by the diluted N₂ for ΔIt seconds.

(3) After the purge of the processing chamber 1 inside, a remote plasma oxygen, as the secondary raw material, having been obtained by activating the oxygen by the remote plasma unit 11 is introduced into the processing chamber 1 for ΔRt seconds. Also during this time, the diluted N₂ is being continued to be introduced.

(4) If the introduction of the remote plasma oxygen is stopped, the processing chamber 1 inside is purged by the diluted N₂ for ΔIt seconds again.

(5) A step (1 cycle) from these (1) to (4) is repeated (n cycles) till the film thickness reaches to a desired value (thickness). Incidentally, there may be adapted such that, instead of the remote plasma oxygen having been obtained by activating the oxygen by the remote plasma unit 11, there is used a remote plasma argon or a remote plasma nitrogen, which has been obtained by activating the argon or the nitrogen by the remote plasma unit 11.

By the cycle processing like the above, in which the film formation process→the purge process→the reforming process→the purge process is repeated by plural times, it is possible to form the HfO₂ thin film of a predetermined film thickness, in which a mixing of CH and OH is extremely little.

Incidentally, it is desirable that the film formation process and the reforming process are performed at approximately the same temperature (it is desirable that a setting temperature of the heater is made constant without being altered). This is because, by causing a temperature fluctuation not to occur, the particles due to a thermal expansion of a peripheral member such as the shower head or the susceptor become difficult to generate and, further, it is possible to suppress a running-out of a metal (metallic contamination) from metal components.

After the HfO₂ thin film of the predetermined film thickness has been formed on the substrate 4, the substrate 4 is transported out of the processing chamber 1.

After the formation of the HfO₂ thin film of the predetermined film thickness to the substrate 4 has been repeatedly performed to the substrates of predetermined pieces, when the thickness of the film having deposited to the processing chamber 1 inside has reached to a limit film thickness (about 50-1000 nm), it enters into the cleaning process. In the cleaning process, the valve 59 having been provided in the supply pipe 53 is opened, and the Ar having been supplied from the Ar supply unit 48 is flow-rate-controlled by the mass flow controller 56 to thereby be supplied to the reactant activation unit 11, thereby generating the Ar plasma. After the Ar plasma has been generated, the valve 60 having been provided in the supply pipe 54 is opened, and the ClF₃ having been supplied from the ClF₃ supply unit 49 is flow-rate-controlled by the mass flow controller 57 to thereby be supplied to the reactant activation unit 11 which is generating the Ar plasma, thereby activating the ClF₃. By this, there is generated the chlorine radical (Cl*) or the fluorine radical (F*). After the chlorine radical (Cl*) or the fluorine radical (F*) has been generated, the valve 24 having been provided in the radical supply pipe 13 is opened, thereby introducing the chlorine radical (Cl*) or the fluorine radical (F*) to the inside of the processing chamber 1 through the shower head 6. Since the F* or the Cl*, which has been activated by the remote plasma, passes through the HfO₂ film without substantially reacting with the HfO₂ film to thereby react with the pre-coating film consisting of the SiO₂ or the Si and thus the pre-coating film is exfoliated into pieces, it is possible to remove together also the HfO₂ film existing thereon. Thereafter, by the purge process, there are removed the cleaning gas having remained in the processing chamber 1 inside, a product having been generated at a cleaning time, and a substance having been exfoliated by the cleaning.

Third Implementation Mode:

Next, there is explained about the third implementation mode of the present invention.

This third implementation mode is one in which, when forming a silicate film that is a metal oxide having contained the silicon, the present invention has been applied to a film forming method repeating the film formation by the MOCVD method and the reforming process of the film.

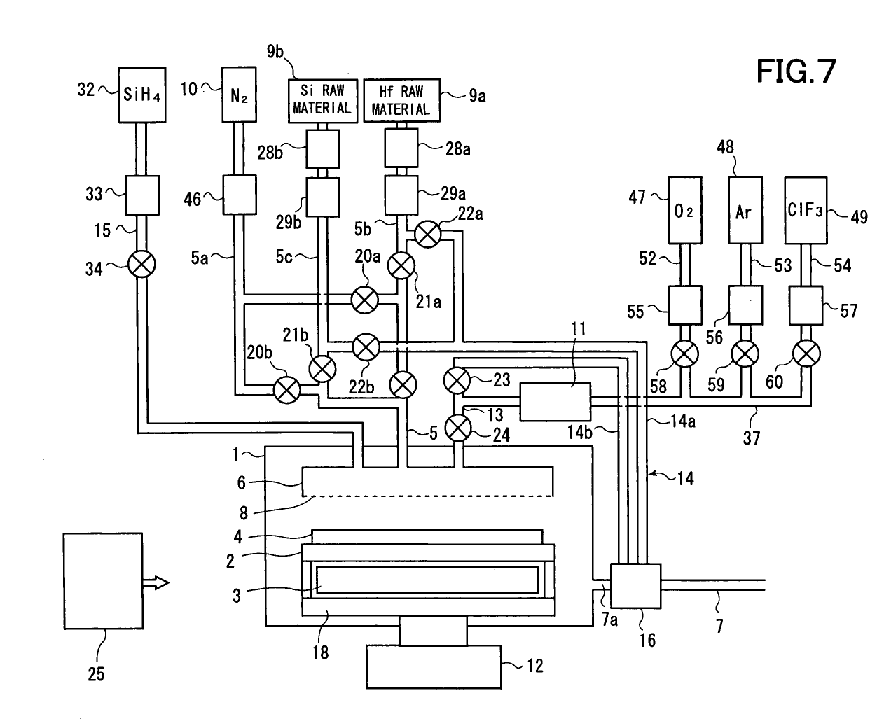

FIG. 7 is a schematic view showing one example of the leaf system CVD apparatus that is the apparatus for processing the substrate, which has been used in the third implementation mode.

Since a matter differing from the second implementation mode of FIG. 5 is only a raw material supply system and other portion is the same, here there is explained only the raw material supply system in the apparatus for processing the substrate.

Above the susceptor 2 in the processing chamber 1 there is provided the shower head 6 having the many holes 8. To this shower head 6, there are connected in common the pre-coating gas supply pipe 15 for supplying the pre-coating gas, the raw material supply pipe 5 for supplying the film forming gas, and the radical supply pipe 13 for supplying the radical capable of activating the reforming gas and the radical capable of activating the cleaning gas, and thereby there is adapted such that the pre-coating gas, the film forming gas or the radicals can be jetted like the shower into the processing chamber 1 from the shower head 6. Here, the shower head 6 constitutes the same supply port for supplying respectively the pre-coating gas to be supplied into the processing chamber 1 in the pre-coating process, the film forming gas to be supplied to the substrate 4 in the film forming process, and the radical capable of activating the reforming gas to be supplied to the substrate 4 in the reforming process and the radical capable of activating the cleaning gas to be supplied into the processing chamber 1 in the cleaning process.

Outside the processing chamber, there are provided the pre-coating gas supply unit 32 that is the supply source of the pre-coating gas, the mass flow controller 33 as the flow rate control means for controlling the supply quantity of the pre-coating gas, and the valve 34. To the pre-coating gas supply pipe 15, there are connected the pre-coating gas supply unit 32, the mass flow controller 33 and the valve 34, and thereby there is adapted such that the pre-coating gas is supplied to the processing chamber 1 inside by opening the valve 34 in the process of pre-coating the processing chamber 1 inside. The pre-coating gas is the SiH₄ or the Si₂H₆ similarly to the first implementation mode and the second implementation mode, which have been mentioned before.

Further, outside the processing chamber 1, there are provided a 1st film forming raw material supply unit 9a for supplying the organic liquid raw material as a 1st film forming raw material, a 1st liquid flow rate control device 28a as a flow rate control means for controlling a liquid supply flow rate of the 1st film forming raw material, and a 1st vaporizer 29a for vaporizing the 1st film forming raw material. Further, there are provided a 2nd film forming raw material supply unit 9b for supplying the organic liquid raw material as a 2nd film forming raw material, a 2nd liquid flow rate control device 28b as a flow rate control means for controlling a liquid supply flow rate of the 2nd film forming raw material, and a 2nd vaporizer 29b for vaporizing the 2nd film forming raw material. Further, there are provided the inert gas supply unit 10 for supplying the inert gas as the non-reactive gas, and the mass flow controller 46 as the flow rate control means for controlling the supply flow rate of the inert gas.

As the 1st film forming raw material there is used the organic material such as Hf-(MMP)₄ that is a liquid raw material containing a metal. As the 2nd film forming raw material there is used an organic material such as Si[OC(CH₃)₂CH₂OCH₃]₄ (hereafter, abbreviated as Si-(MMP)₄). Further, as the inert gas there is used Ar, He, N₂ or the like.

By making the 1st raw material gas supply pipe 5b having been provided in the 1st film forming raw material unit 9a, a 2nd raw material gas supply pipe 5c having been provided in the 2nd film forming raw material supply unit 9b and the inert gas supply pipe 5a having been provided in the inert gas supply unit 10 into one piece, there is provided the raw material supply pipe 5 connected to the shower head 6. Incidentally, the inert gas supply pipe 5a branches in a downstream side than the mass flow controller 46 and is connected respectively to the 1st raw material gas supply pipe 5b and the 2nd raw material gas supply pipe 5c.

There is adapted such that, in the film formation process of forming an Hf silicate film onto the substrate 4, the raw material supply pipe 5 supplies the mixed gas of the film forming gas and the inert gas to the shower head 6. In the 1st raw material gas supply pipe 5b, the 2nd raw material gas supply pipe 5c, one inert gas supply pipe 5a having been branched and the other inert gas supply pipe 5a having been branched, there are provided respectively valves 21a, 21b, 20a and 20b and, by opening/closing these valves 21a, 21b, 20a and 20b, it becomes possible to control the supply of the mixed gas of the film forming gas and the inert gas.

Further, in the 1st raw material gas supply pipe 5b and the 2nd raw material gas supply pipe 5c, there is provided the raw material gas bypass pipe 14a connected to the raw material recovery trap 16 having been provided in the exhaust pipe 7. The raw material gas bypass pipe 14a is plumbed to each of the 1st raw material gas supply pipe 5b and the 2nd raw material gas supply pipe 5c, and made into one piece in its downstream side. To the raw material gas bypass pipe 14a having been connected to the 1st raw material gas supply pipe 5b and the raw material gas bypass pipe 14a having been connected to the 2nd raw material gas supply pipe 5c, there are provided respectively the valves 22a, 22b. By opening/closing these valves, it is possible to make such that the film forming gas is supplied to the substrate 4 in the processing chamber 1 in the film formation process, or it is exhausted through the raw material gas bypass pipe 14a and the raw material recovery trap 16 so as to bypass the processing chamber 1 without stopping the supply of the film forming gas from the vaporizers 29a, 29b in the reforming process.

And, there is provided the control device 25 which, by controlling the open/close or the like of the above valves 20a, 20b, 21a, 21b, 22a, 22b, 23 and 24, controls so as to continuously repeat, by plural times, the film formation process of forming the Hf silicate film on the substrate 4 in the processing chamber 1, and the reforming process of removing the impurities, such as C and H, that are specified elements in the Hf silicate film having been formed in the film formation process by the plasma processing having used the reactant activation unit 11.

Next, there is explained about the method of manufacturing the semiconductor device by using the apparatus for processing the substrate of the above-mentioned constitution.

In the above constitution, first, the SiO₂ or Si film is thinly pre-coated previously to the inside of the processing chamber 1 by the CVD method by opening the valve 34 having been provided in the supply pipe 15, flow-rate-controlling the SiH₄ or Si₂H₆ gas which has been supplied from the pre-coating gas supply unit 32, and introducing it to the processing chamber 1 in which the film formation processing is not performed yet (pre-coating process). Incidentally, in the case where the SiO₂ film is used as the pre-coating film, the O₂ gas having been supplied from the oxygen supply unit 47 by simultaneously opening the valve 58 having been provided in the supply pipe 52 and the valve 24 having been provided in the radical supply pipe 13 is introduced into the processing chamber 1 while being flow-rate-controlled by the mass flow controller 55. At this time, the reactant activation unit 11 does not operate, and the O₂ gas is supplied without being activated.

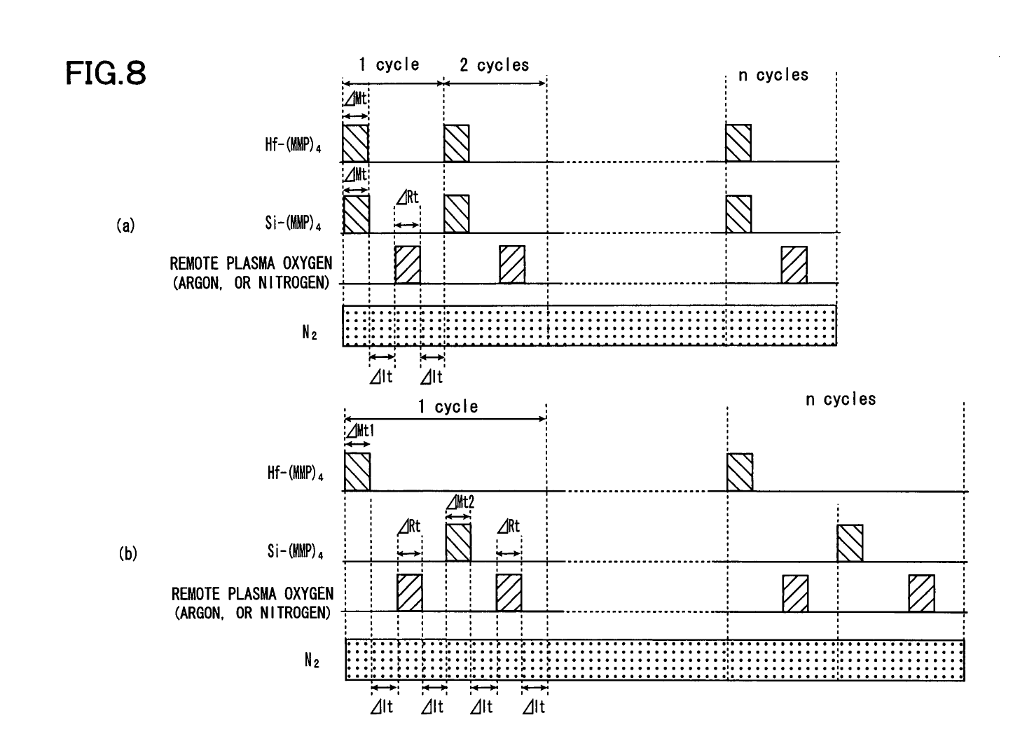

Next, a high quality Hf silicate film is formed on the substrate by such a film formation sequence as shown in FIG. 8.

That is, in a case of the sequence of FIG. 8(a), if the substrate 4 is transported into the processing chamber 1, the substrate 4 is mounted on the susceptor 2 in the processing chamber 1 and the temperature of the substrate 4 has stabilized,

(1) The Hf-(MMP)₄ and the Si-(MMP)₄ are introduced, together with the diluted N₂, into the processing chamber 1 for ΔMt seconds. By this, the Hf silicate film is deposited onto the substrate 4.

(2) Thereafter, if the introductions of the Hf-(MMP)₄ and the Si-(MMP)₄ are stopped with the introduction of the diluted N₂ being continued intact, the processing chamber 1 inside is purged by the diluted N₂ for ΔIt seconds.

(3) After the purge of the processing chamber 1 inside, the remote plasma oxygen, as the secondary raw material, having been obtained by activating the oxygen by the remote plasma unit 11 is introduced into the processing chamber 1 for ΔRt seconds. By this, the impurities, such as C and H, are removed from the Hf silicate film having been formed on the substrate 4. Also during this time, the diluted N₂ is being continued to be introduced.

(4) If the introduction of the remote plasma oxygen is stopped with the introduction of the diluted N₂ being continued intact, the processing chamber 1 inside is purged by the diluted N₂ for ΔIt seconds again.

(5) A step (1 cycle) from these (1) to (4) is repeated (n cycles) till the film thickness of the Hf silicate film reaches to a desired value (thickness). Incidentally, there may be adapted such that, instead of the remote plasma oxygen having been obtained by activating the oxygen by the remote plasma unit 11, there is used the remote plasma argon or the remote plasma nitrogen, which has been obtained by activating the argon or the nitrogen by the remote plasma unit 11. After the Hf silicate film of the desired film thickness has been formed on the substrate 4, the substrate 4 is transported out of the processing chamber 1.

In a case of the sequence of FIG. 8(b), if the substrate 4 is transported into the processing chamber 1, the substrate 4 is mounted on the susceptor 2 in the processing chamber 1 and the temperature of the substrate 4 has stabilized,

(1) The Hf-(MMP)₄ is introduced, together with the diluted N₂, into the processing chamber 1 for ΔMt1 seconds.

(2) Thereafter, if the introduction of the Hf-(MMP)₄ is stopped with the introduction of the diluted N₂ being continued intact, the processing chamber 1 inside is purged for ΔIt seconds.

(3) After the purge of the processing chamber 1 inside, the remote plasma oxygen, as the secondary raw material, having been obtained by activating the oxygen by the remote plasma unit 11 is introduced into the processing chamber 1 for ΔRt seconds. Also during this time, the diluted N₂ is being continued to be introduced.

(4) If the introduction of the remote plasma oxygen is stopped with the introduction of the diluted N₂ being continued intact, the processing chamber 1 inside is purged for ΔIt seconds again.

(5) After the purge of the processing chamber 1 inside, the Si-(MMP)₄ is introduced, together with the diluted N₂, into the processing chamber 1 for ΔMt2 seconds.

(6) Thereafter, if the introduction of the Si-(MMP)₄ is stopped with the introduction of the diluted N₂ being continued intact, the processing chamber 1 inside is purged by the diluted N₂ for ΔIt seconds.

(7) After the purge of the processing chamber 1 inside, the remote plasma oxygen, as the secondary raw material, having been obtained by activating the oxygen by the remote plasma unit 11 is introduced into the processing chamber 1 for ΔRt seconds. Also during this time, the diluted N₂ is being continued to be introduced.

(8) If the introduction of the remote plasma oxygen is stopped with the introduction of the diluted N₂ being continued intact, the processing chamber 1 inside is purged for ΔIt seconds again.

(9) By a step (1 cycle) of these (1) to (8), the Hf silicate film from which the impurities, such as C and H, have been removed is formed on the substrate 4, and the step (1 cycle) from these (1) to (8) is repeated (n cycles) till the film thickness of the Hf silicate film reaches to the desired value (thickness). Incidentally, there may be adapted such that, instead of the remote plasma oxygen having been obtained by activating the oxygen by the remote plasma unit 11, there is used the remote plasma argon or the remote plasma nitrogen, which has been obtained by activating the argon or the nitrogen by the remote plasma unit 11.

After the Hf silicate film of the desired film thickness has been formed on the substrate 4, the substrate 4 is transported out of the processing chamber 1.

After the formation of the Hf silicate film of the predetermined film thickness to the substrate 4 has been repeatedly performed to the substrates of predetermined pieces, when the thickness of the film having deposited to the processing chamber 1 inside has reached to the limit film thickness, it enters into the cleaning process. In the cleaning process, the valve 59 having been provided in the supply pipe 53 is opened, and the Ar having been supplied from the Ar supply unit 48 is flow-rate-controlled by the mass flow controller 56 to thereby be supplied to the reactant activation unit 11, thereby generating the Ar plasma. After the Ar plasma has been generated, the valve 60 having been provided in the supply pipe 54 is opened, and the ClF₃ having been supplied from the ClF₃ supply unit 49 is flow-rate-controlled by the mass flow controller 57 to thereby be supplied to the reactant activation unit 11 which is generating the Ar plasma, thereby activating the ClF₃. By this, there is generated the chlorine radical (Cl*) or the fluorine radical (F*). After the chlorine radical (Cl*) or the fluorine radical (F*) has been generated, the valve 24 having been provided in the radical supply pipe 13 is opened, thereby introducing the chlorine radical (Cl*) or the fluorine radical (F*) to the inside of the processing chamber 1 through the shower head 6. Since the F* or the Cl*, which has been activated by the remote plasma, passes through the Hf silicate film without substantially reacting with the Hf silicate film to thereby react with the pre-coating film consisting of the SiO₂ or Si and thus the pre-coating film is exfoliated into pieces, it is possible to remove together also the Hf silicate film existing thereon. Thereafter, by the purge process, there are removed the cleaning gas having remained in the processing chamber 1 inside, the product having been generated at the cleaning time, and the substance having been exfoliated by the cleaning.

Fourth Implementation Mode:

Next, there is explained about the fourth implementation mode of the present invention.

This fourth implementation mode is one in which, in a case where the HfO₂ film of amorphous state is formed by an ALD (Atomic Layer Deposition) method by an alternate supply of the organic raw material and the remote plasma oxygen, the present invention has been applied.

There is explained about a method of forming the film by the ALD method by using the apparatus of FIG. 5 (the second implementation mode).

First, the SiO₂ or Si film is thinly pre-coated previously to the inside of the processing chamber 1 by the CVD method by opening the valve 34 having been provided in the supply pipe 15, flow-rate-controlling the SiH₄ or Si₂H₆ gas which has been supplied from the pre-coating gas supply unit 32, and introducing it to the processing chamber 1 in which the film formation is not performed yet (pre-coating process). Incidentally, in the case where the SiO₂ film is used as the pre-coating film, the O₂ gas having been supplied from the oxygen supply-unit 47 by simultaneously opening the valve 58 having been provided in the supply pipe 52 and the valve 24 having been provided in the radical supply pipe 13 is introduced into the processing chamber 1 while being flow-rate-controlled by the mass flow controller 55. At this time, the reactant activation unit 11 does not operate, and the O₂ gas is supplied without being activated.

Subsequently, it follows that the film formation is made by a sequence like the following. Incidentally, a manner of flowing the gas is the same as one having shown in FIG. 6 (the second implementation mode).

That is, if the substrate 4 is transported into the processing chamber 1, the substrate 4 is mounted on the susceptor 2 in the processing chamber 1 and the temperature of the substrate 4 has stabilized,

(1) The Hf-(MMP)₄ as an HF raw material is introduced, together with the diluted N₂, into the processing chamber 1 for ΔMt seconds. By this, the Hf-(MMP)₄ is caused to be adsorbed onto the substrate 4.

(2) Thereafter, if the introduction of the Hf-(MMP)₄ is stopped with the introduction of the diluted N₂ being continued intact, the processing chamber 1 inside is purged by the diluted N₂ for ΔIt seconds.

(3) After the purge of the processing chamber 1 inside, the remote plasma oxygen, as the secondary raw material, having been obtained by activating the oxygen by the remote plasma unit 11 is introduced into the processing chamber 1 for ΔRt seconds. By this, the remote plasma oxygen is reacted with the Hf-(MMP)₄ having been adsorbed onto the substrate 4, thereby forming the HfO₂ film onto the substrate 4. Also during this time, the diluted N₂ is being continued to be introduced.

(4) If the introduction of the remote plasma oxygen is stopped with the introduction of the diluted N₂ being continued intact, the processing chamber 1 inside is purged by the diluted N₂ for ΔIt seconds again.

(5) A step (1 cycle) from these (1) to (4) is repeated (n cycles) till the film thickness of the HfO₂ film reaches to a desired value (thickness). By this, it is possible to form the HfO₂ film of the desired film thickness.

After the HfO₂ film of the desired film thickness has been formed on the substrate 4, the substrate 4 is transported out of the processing chamber 1.

After the formation of the HfO₂ thin film of the predetermined film thickness to the substrate 4 has been repeatedly performed to the substrates of predetermined pieces, when the thickness of the film having deposited to the processing chamber 1 inside has reached to the limit film thickness (about 50-1000 nm), it enters into the cleaning process. In the cleaning process, the valve 59 having been provided in the supply pipe 53 is opened, and the Ar having been supplied from the Ar supply unit 48 is flow-rate-controlled by the mass flow controller 56 to thereby be supplied to the reactant activation unit 11, thereby generating the Ar plasma. After the Ar plasma has been generated, the valve 60 having been provided in the supply pipe 54 is opened, and the ClF₃ having been supplied from the ClF₃ supply unit 49 is flow-rate-controlled by the mass flow controller 57 to thereby be supplied to the reactant activation unit 11 which is generating the Ar plasma, thereby activating the ClF₃. By this, there is generated the chlorine radical (Cl*) or the fluorine radical (F*). After the chlorine radical (Cl*) or the fluorine radical (F*) has been generated, the valve 24 having been provided in the radical supply pipe 13 is opened, thereby introducing the chlorine radical (Cl*) or the fluorine radical (F*) to the inside of the processing chamber 1 through the shower head 6. Since the F* or the Cl*, which has been activated by the remote plasma, passes through the HfO₂ film to thereby react with the pre-coating film consisting of the SiO₂ or the Si and thus the pre-coating film is exfoliated into pieces, it is possible to remove together also the HfO₂ film existing thereon. Thereafter, these products are removed by the purge process.

Incidentally, in the above implementation modes, although there have been explained about the case where, by the CVD method or the ALD method, the HfO₂ is film-formed as the High-k film by using the Hf-(MMP)₄ as the raw material and the case where the Hf silicate film is formed by using the Hf-(MMP)₄ and the Si-(MMP)₄, other than these there can be applied to the film formation of all High-k films such as a case where the HfO₂ is film-formed by using the HfCl₄ and TDEAHf (Hf[N(C₂H₅)₂]₄) and a case where Al₂O₃ is film-formed by using TMA (Al(CH₃)₃). Additionally, not limited to the film formation of the High-k film, there can be applied also to a case where, by using a raw material containing Ta, Ti, Ru or the like, there is formed a metal film, a metal oxide film or a metal nitride film, and the like.

### INDUSTRIAL APPLICABILITY

The present invention can be utilized to a method of manufacturing a semiconductor device, in which it is necessary to perform a self-cleaning.

1. A method of manufacturing a semiconductor device, comprising the steps of:
pre-coating a pre-coating film, which differs from a film to be formed to a substrate, to a processing chamber inside,
forming the film to the substrate in the processing chamber after the pre-coating, and
cleaning the processing chamber inside by supplying a reactant into the processing chamber after forming the film,
wherein, in the cleaning step, the film adhered to the processing chamber inside is removed together with the pre-coating film by reacting the reactant with the pre-coating film without substantially reacting with the film adhered to the processing chamber inside in the film forming step.

2. A method of manufacturing a semiconductor device, comprising the steps of:
pre-coating a pre-coating film, which differs from a film to be formed to a substrate, to a processing chamber inside,
forming the film to the substrate in the processing chamber after the pre-coating, and
cleaning the processing chamber inside by supplying a reactant into the processing chamber after forming the film,
wherein, in the cleaning step, a film adhered to the processing chamber inside is removed together with the pre-coating film by making such that an etching rate of the pre-coating film becomes higher than an etching rate of the film adhered to the processing chamber inside in the film forming step.

3. A method of manufacturing a semiconductor device, comprising the steps of:
pre-coating a pre-coating film, which consists of a material other than a High-k film, to a substrate processing chamber inside,
forming the High-k film to a substrate in the processing chamber after the pre-coating, and
cleaning the processing chamber inside by supplying a reactant into the processing chamber after forming the film,
wherein, in the cleaning step, the High-k film adhered to the processing chamber inside is removed together with the pre-coating film by making a cleaning temperature into a temperature of such a degree that the reactant reacts with the pre-coating film without reacting with the High-k film adhered to the processing chamber inside.

4. A method of manufacturing a semiconductor device, comprising the steps of:
pre-coating a pre-coating film, which consists of a material other than a High-k film, to a substrate processing chamber inside,
forming the High-k film to a substrate in the processing chamber after the pre-coating, and
cleaning the processing chamber inside by supplying a reactant into the processing chamber after forming the film,
wherein, in the cleaning step, a cleaning temperature is made a temperature within a range not lower than 100° C. and not higher than 400° C.

5. A method of manufacturing a semiconductor device according to claim 1, wherein, in the film forming step, a High-k film is formed.

6. A method of manufacturing a semiconductor device according to claim 5, wherein the High-k film is a film containing Hf.

7. A method of manufacturing a semiconductor device according to claim 6, wherein the film containing Hf is an HfO₂ film or an Hf silicate film.

8. A method of manufacturing a semiconductor device according to claim 5, wherein, in the pre-coating step, a film containing Si is pre-coated.

9. A method of manufacturing a semiconductor device according to claim 8, wherein the film containing Si is a film of at least one kind selected from a group consisting of SiO₂, Si or SiC.

10. A method of manufacturing a semiconductor device according to claim 8, wherein the reactant used in the cleaning step contains F or Cl.

11. A method of manufacturing a semiconductor device according to claim 8, wherein the reactant used in the cleaning step is an active species obtained by activating a gas containing F or Cl by a plasma.

12. A method of manufacturing a semiconductor device according to claim 8, wherein the reactant used in the cleaning step is an active species obtained by activating a mixed gas of a gas containing F or Cl and Ar by a plasma.

13. A method of manufacturing a semiconductor device according to claim 8, wherein the reactant used in the cleaning step is F* or Cl*.

14. A method of manufacturing a semiconductor device according to claim 8, wherein, in the cleaning step, a cleaning temperature is made a temperature within a range not lower than 100° C. and not higher than 400° C.

15. A method of manufacturing a semiconductor device according to claim 10, wherein, in the processing chamber inside, an Al-made member exists.

16. A method of manufacturing a semiconductor device according to claim 10, wherein the processing chamber is a cold wall type.
